(19) United States
(12) Patent Application Publication
(10) Pub. No.: US 2007/0131967 A1
(43) Pub. Date: Jun. 14, 2007

(54) Self-standing GaN single crystal substrate, method of making same, and method of making a nitride semiconductor device

(75) Inventors: Yusuke Kawaguchi, Edogawa (JP); Takeshi Meguro, Hitachi (JP)

Correspondence Address: FOLEY AND LARDNER LLP;SUITE 500, 3000 K STREET NW, WASHINGTON, DC, 20007, US

(73) Assignee: HITACHI CABLE, LTD.

(21) Appl. No.: 11/413,115

(22) Filed: Apr. 28, 2006

(30) Foreign Application Priority Data
Dec. 8, 2005 (JP) 2005-354454

(51) Int. Cl. H01L 31/00

(52) U.S. Cl. 257/190

(57) ABSTRACT

A self-standing gallium nitride-based semiconductor single crystal substrate has a surface (Ga-face) mirror-polished, and a rear surface (N-face) having an arithmetic mean roughness Ra of 1 micrometer or more and 10 micrometers or less. A nitride semiconductor device is fabricated such that, before the gallium nitride-based semiconductor single crystal substrate is attached to a substrate holder of a vapor phase growth apparatus, the substrate is adjusted such that its rear surface (N-face) has a arithmetic mean roughness Ra to be in face-to-face contact with the substrate holder.

The present application is based on Japanese patent application No. 2005-354454, the entire contents of which are incorporated herein by reference.

### BACKGROUND OF THE INVENTION

1. Field of the Invention

This invention relates to a self-standing GaN-based single crystal substrate (herein also called simply GaN self-standing substrate or self-standing GaN single crystal substrate) and, in particular, to a self-standing GaN-based single crystal substrate that can enhance the non-defective product yield of a nitride semiconductor device. Also, this invention relates to a method of making the self-standing GaN-based single crystal substrate and a method of making the nitride semiconductor device by using the self-standing GaN-based single crystal substrate.

2. Description of the Related Art

Nitride-based semiconductor materials have a wide bandgap and are of direct transition type. Therefore, they are great deal applied to short-wavelength light emitting devices.

A nitride semiconductor device can be fabricated by conducting an epitaxial growth on an underlying substrate by using a vapor-phase growth method such as metalorganic vapor phase epitaxy (MOVPE), molecular beam epitaxy (MBE) and hydride vapor phase epitaxy (HVPE).

The nitride semiconductor devices obtained by the above growth method have a number of crystal defects therein. The crystal defect can cause deterioration in characteristics of the nitride semiconductor device or short lifetime thereof. Therefore, it is desirable to reduce the crystal defect.

A reason for increasing the crystal defect of the nitride semiconductor device is assumed that none of hetero-underlying substrates is lattice-matched to nitride semiconductors. Thus, a GaN self-standing substrate is desired which can be lattice-matched to the nitride semiconductors.

The GaN self-standing substrate is made mainly by HVPE due to the advantage of growth speed. A GaN thick film is grown on a sapphire substrate by HVPE. Then, by removing the sapphire substrate by mechanical polishing or laser separation, the GaN self-standing substrate can be obtained.

The GaN self-standing substrate thus made has still a number of defects. When a nitride semiconductor device is fabricated on the substrate with many crystal defects, the nitride semiconductor device must have many crystal defects. Therefore, in order to reduce the defect of the nitride semiconductor device, it is necessary to reduce the defect of the GaN self-standing substrate. ELO (epitaxial lateral overgrowth) etc. is conducted to reduce the defect of the GaN self-standing substrate.

However, the as-grown GaN self-standing substrate thus obtained cannot be used directly as a substrate for nitride semiconductor growth since it does not have a sufficient surface flatness or it has a large warping.

Therefore, in general, the GaN self-standing substrate is treated by mirror-polishing both of its surface and rear surface (See JP-A-2005-263609, paragraphs [0033] and [0036]). The mirror-polished GaN self-standing substrate is transparent to visible light and infrared rays.

In a hot-wall type furnace, heat conduction to the GaN self-standing substrate is performed by heat conduction from a substrate holder and heat radiation of a heater. Thus, uniformity in temperature of the GaN self-standing substrate depends upon heat distribution of the substrate holder and degree of the contact between the GaN self-standing substrate and the substrate holder.

Although the mirror-polished GaN self-standing substrate is flat (10 nm or less in arithmetic mean roughness) in its rear surface, the substrate holder is roughed (about 10 micrometers in arithmetic mean roughness) in its surface as compared to the mirror surface. Thus, since they are too different each other in roughness, the mirror-polished GaN self-standing substrate is in point-contact with the substrate holder. The degree of contact is inferior to the case of face-to-face contacting.

In order to have in-plane uniformity in temperature distribution of the GaN self-standing substrate, it is necessary to enhance the degree of contact with the substrate holder at any places on the rear surface of the GaN self-standing substrate, as well as to reduce the warping of the GaN self-standing substrate.

### SUMMARY OF THE INVENTION

It is an object of the invention to provide a self-standing GaN single crystal substrate that can enhance the non-defective product yield of a nitride semiconductor device.

It is a further object of the invention to provide a method of making the self-standing GaN single crystal substrate, and a method of making the nitride semiconductor device by using the self-standing GaN single crystal substrate.

(1) According to one aspect of the invention, a self-standing gallium nitride-based semiconductor single crystal substrate comprises:

a surface (Ga-face) mirror-polished; and

a rear surface (N-face) comprising an arithmetic mean roughness Ra of 1 micrometer or more and 10 micrometers or less.

(2) According to another aspect of the invention, a method of making a self-standing gallium nitride-based semiconductor single crystal substrate comprises:

a surface treatment step that a surface (Ga-face) of the substrate is mirror-polished; and

a rear-surface treatment step that a rear surface (N-face) of the substrate is lapped and then etched.

(3) According to another aspect of the invention, a method of making a nitride semiconductor device comprises the step of:

growing the nitride semiconductor device on the gallium nitride-based semiconductor single crystal substrate made by the method as defined in (2) by a vapor phase growth method.

In the above inventions (2)-(3), the following modifications and changes can be made.

(i) The rear-surface treatment step is conducted such that the rear surface (N-face) comprising an arithmetic mean roughness Ra of 1 micrometer or more and 10 micrometers or less.

(4) According to another aspect of the invention, a method of making a nitride semiconductor device comprises:

providing a self-standing gallium nitride-based semiconductor single crystal substrate; and

an adjustment step that, before the gallium nitride-based semiconductor single crystal substrate is attached to a substrate holder of a vapor phase growth apparatus, the gallium nitride-based semiconductor single crystal substrate is adjusted such that its rear surface (N-face) comprises a arithmetic mean roughness Ra to be in face-to-face contact with the substrate holder.

In the above invention (4), the following modifications and changes can be made.

(ii) The adjustment step comprises etching the rear surface of the substrate.

(iii) The adjustment step comprises adjusting the arithmetic mean roughness Ra to be 1 micrometer or more and 10 micrometers or less.

### ADVANTAGES OF THE INVENTION

In accordance with the invention, the self-standing GaN single crystal substrate can enhance the non-defective product yield of a nitride semiconductor device by improving the degree of contact with the substrate holder while reducing the warping of the GaN self-standing substrate.

### BRIEF DESCRIPTION OF THE DRAWINGS

The preferred embodiments according to the invention will be explained below referring to the drawings, wherein:

FIG. 1 is a schematic side view showing a GaN semiconductor single crystal substrate in a preferred embodiment according to the invention;

FIG. 2A is a flow chart showing a conventional method of making a GaN self-standing substrate (i.e., its surface and rear surface being mirror-polished);

FIG. 2B is a flow chart showing a method of making a GaN self-standing substrate in a preferred embodiment according to the invention;

FIG. 3 is a schematic cross sectional view showing a nitride semiconductor device in a preferred embodiment according to the invention; and

FIG. 4 is a graph showing the non-defective product yield of nitride semiconductor devices fabricated in Examples 1-3 and Comparative Examples 1-3.

### DETAILED DESCRIPTION OF THE PREFERRED EMBODIMENTS

Construction of GaN Semiconductor Single Crystal Substrate in Embodiment

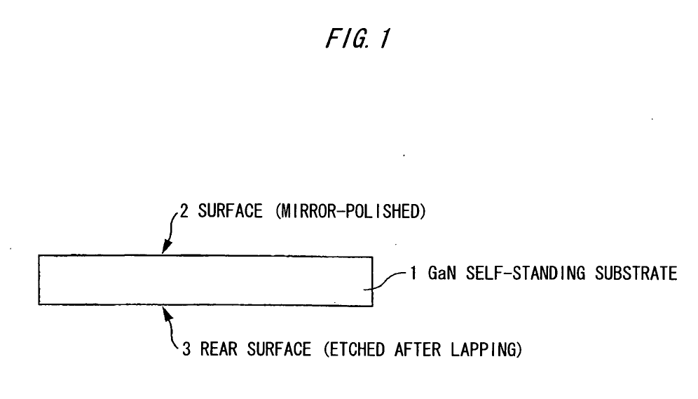

FIG. 1 is a schematic side view showing a GaN semiconductor single crystal substrate in the preferred embodiment according to the invention.

A GaN self-standing substrate (=GaN semiconductor single crystal substrate) 1 of the embodiment is characterized by that its surface (Ga-face) 2 is mirror-polished and its rear surface (N-face) 3 has an arithmetic mean roughness Ra of 1 micrometer or more and 10 micrometers or less. The arithmetic mean roughness Ra is determined in the range of 50 micrometers×50 micrometers by using an atomic force microscope according to JIS B 0601-1994.

Method of Making the GaN Semiconductor Single Crystal Substrate in Embodiment

A method of making the GaN self-standing substrate in the preferred embodiment of the invention will be explained as compared to the conventional method.

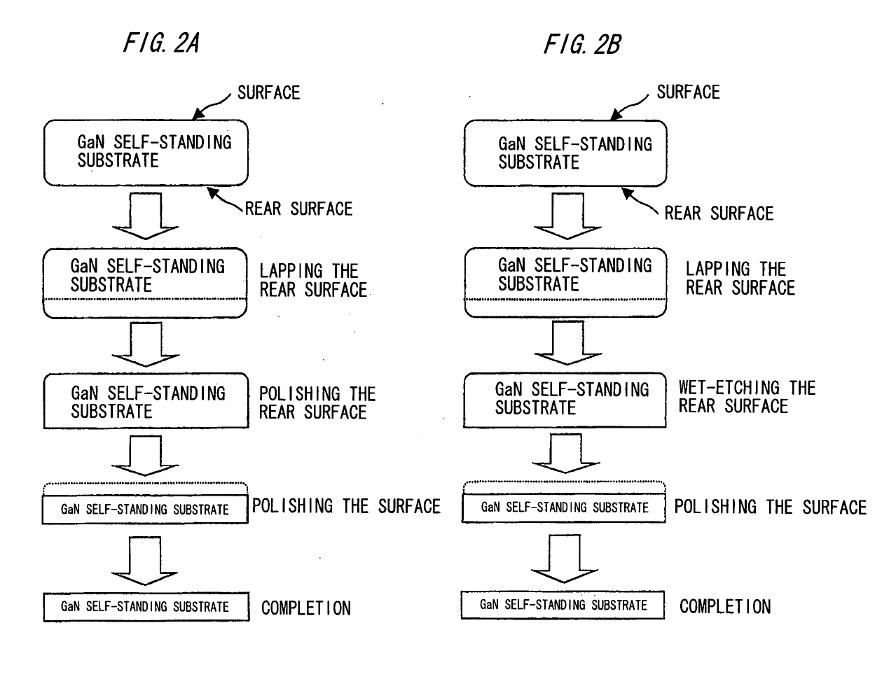

FIG. 2A is a flow chart showing the conventional method of making a GaN self-standing substrate (i.e., its surface and rear surface being mirror-polished). FIG. 2B is a flow chart showing a method of making a GaN self-standing substrate in the preferred embodiment according to the invention.

The method of making a GaN self-standing substrate in the embodiment comprises a surface treatment step to mirror-polish the surface (Ga-face), and a rear surface treatment step to etch the rear surface (N-face) after lapping it. Thereby, the rear surface (N-face) can have an arithmetic mean roughness of 1 micrometer or more and 10 micrometers or less.

For example, after a sapphire substrate is pretreated by ELO etc., a GaN thick film is formed thereon by HVPE. Then, the sapphire substrate is removed by mechanical polishing or laser separation to have a GaN self-standing substrate.

The GaN self-standing substrate obtained cannot be used directly as a substrate for nitride semiconductor device, and therefore the GaN self-standing substrate is polished at both surfaces.

The rear surface is first polished. It is polished by grinding or lapping (with GC #800 etc.).

In the conventional method as shown in FIG. 2A, the rear surface is then mirror-polished. In contrast, in the embodiment as shown in FIG. 2B, the rear surface is etched by using an alkali aqueous solution such as NaOH aqueous solution and KOH aqueous solution, or a mixed solution of hydrochloric acid and hydrogen peroxide solution, whereby the arithmetic mean roughness can be 1 micrometer or more and 10 micrometers or less.

Although the surface of the GaN self-standing substrate is strain-free, the rear surface thereof has a process-strained layer since it is polished. Therefore, after the polishing of the rear surface, a warping is generated since stress balance of the entire substrate is collapsed. In the embodiment of the invention, the process-strained layer on the rear surface, which causes the warping, can be removed by the etching thereof to reduce the warping.

After the rear surface is etched, the surface (Ga-face) of the GaN self-standing substrate is lapped and polished to be mirror-finished. Thereby, the GaN self-standing substrate can be completed.

Method of Fabricating a Nitride Semiconductor Device in Embodiment

A method of fabricating the nitride semiconductor device in the preferred embodiment according to the invention will be explained below.

The method of the embodiment comprises fabricating the nitride semiconductor device by a vapor phase growth method by using the GaN self-standing substrate (=self-standing GaN single crystal substrate) made by the above method.

Furthermore, the method of the embodiment comprises fabricating the nitride semiconductor device in a vapor phase growth apparatus by using the GaN self-standing substrate (=self-standing GaN single crystal substrate), wherein the arithmetic mean roughness Ra of the rear surface (N-face) of the GaN self-standing substrate is adjusted to allow the rear surface to be in face-to-face contact with a surface of a substrate holder of the apparatus before the GaN self-standing substrate is attached onto the surface of the substrate holder.

The step of adjusting the arithmetic mean roughness Ra may comprise etching the rear surface of the GaN self-standing substrate. For example, similarly to the etching step in the abovementioned method of making the GaN self-standing substrate, the rear surface is polished by grinding or lapping (with GC #800 etc.) and then it is etched by using an alkali aqueous solution such as NaOH aqueous solution and KOH aqueous solution, or a mixed solution of hydrochloric acid and hydrogen peroxide solution.

The step of adjusting the arithmetic mean roughness Ra may comprise adjusting the arithmetic mean roughness Ra of the rear surface of the GaN self-standing substrate to be 1 micrometer or more and 10 micrometers or less. The adjustment can be conducted by, e.g., the etching step as described above.

The step of adjusting the arithmetic mean roughness Ra may comprise adjusting the arithmetic mean roughness Ra of the rear surface of the GaN self-standing substrate to be in the range of one tenth to equal relative to the arithmetic mean roughness of the substrate holder (i.e., a contact face with the GaN self-standing substrate) of the vapor phase growth apparatus. The adjustment can be conducted by, e.g., the etching step as described above.

Effects of the Embodiment

The effects of the above embodiment are as follows.

(1) The non-defective product yield of the nitride semiconductor device formed on the GaN self-standing substrate can be enhanced by adjusting the rear surface of the GaN self-standing substrate to have a predetermined arithmetic mean roughness. In the conventional method, unevenness in temperature in plane of the GaN self-standing substrate is caused by the low degree of the contact with the substrate holder. However, in the embodiment, since the roughness of the rear surface is adjusted to be the predetermined arithmetic mean roughness, the degree of the contact is enhanced such that the GaN self-standing substrate is face-to-face contacted with the substrate holder. Thereby, heat conduction from the substrate holder to the GaN self-standing substrate can be improved as compared to the conventional GaN self-standing substrate with both surfaces mirror-polished. Therefore, unevenness in temperature distribution in plane of the GaN self-standing substrate can be reduced such that the characteristics after the epitaxial growth are uniformed.

(2) The warping of the GaN self-standing substrate can be reduced by etching the rear surface of the GaN self-standing substrate. Thereby, the non-defective product yield of the nitride semiconductor device formed on the GaN self-standing substrate can be improved.

(3) Since the rear surface of the GaN self-standing substrate is roughed as compared to the case of being mirror-polished, light is scattered thereon such that the rear surface of the GaN self-standing substrate is clouded. Therefore, it can be easy determined which surface of the GaN self-standing substrate appears.

(4) In the step of polishing the rear surface, the number of substrates to be processed is limited. In contrast, the step of etching the rear surface can be suited to the mass production since a number of substrates can be processed once. Therefore, the fabrication cost etc. can be reduced.

### EXAMPLES 1-3

Examples 1-3 according to the invention will be described below. However, the invention is not limited to these.

By using the method of making the GaN self-standing substrate in the embodiment (as shown in FIG. 2B), GaN self-standing substrates are made such that the surface thereof is mirror-polished and the rear surface is treated to be 1 micrometer (=Example 1), 7 micrometers (=Example 2), and 10 micrometers (=Example 3) in arithmetic mean roughness Ra.

In detail, after the GaN self-standing substrate is separated from the sapphire substrate and the rear surface thereof is lapped (with GC #800), the rear surface of the GaN self-standing substrate is polished by etching while being soaked into 1 N NaOH aqueous solution. In this case, the soak time (etch time) in NaOH aqueous solution is adjusted to be 10 min, 30 min and 60 min such that the arithmetic mean roughness Ra of the rear surface of the GaN self-standing substrate is to be 1 micrometer, 7 micrometers and 10 micrometers, respectively.

The warping of the GaN self-standing substrate in Examples 1-3 is determined by measuring the curvature radius before and after the etching of the rear surface. As a result, the curvature radius after the etching is increased to about 2 m than that before the etching, i.e., tens of micrometers. Thus, it is confirmed that the warping of the GaN self-standing substrate can be reduced.

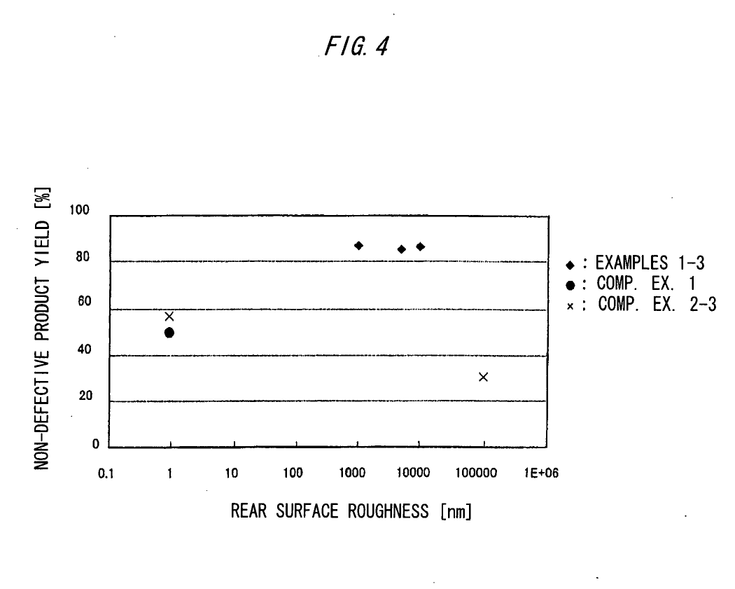

On the other hand, by using the conventional method (as shown in FIG. 2A), a GaN self-standing substrate is made such that the surface and rear surface thereof are mirror-polished (Comparative Example 1, “Comp. Ex. 1” in FIG. 4). Further, by the same method as Examples 1-3, GaN self-standing substrates are made such that the rear surface is treated to be 1 nm (Comparative Example 2, “Comp. Ex. 2” in FIG. 4); 100 micrometers (Comparative Example 3, “Comp. Ex. 3” in FIG. 4) in arithmetic mean roughness Ra.

Then, nitride semiconductor devices are fabricated on the GaN self-standing substrates thus made, and are each evaluated in non-defective product yield.

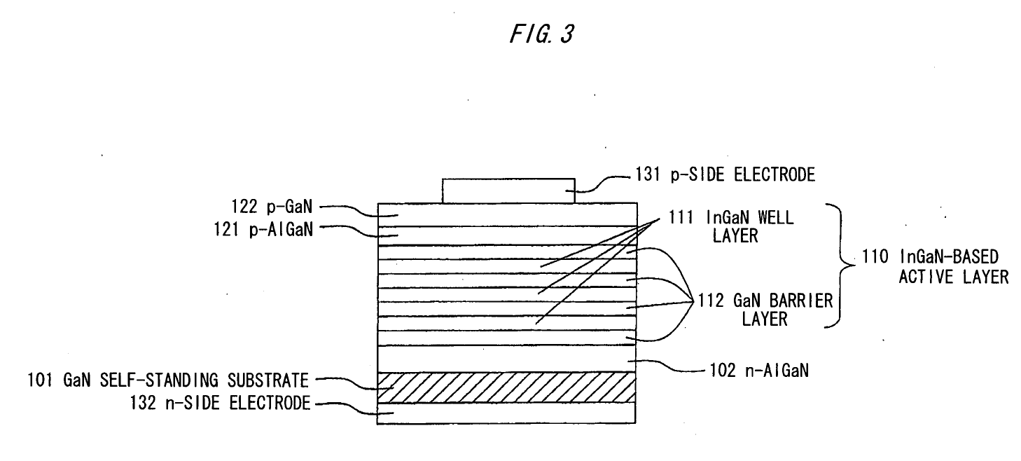

FIG. 3 is a schematic cross sectional view showing a nitride semiconductor device in the preferred embodiment according to the invention.

The nitride semiconductor device of the embodiment has a quantum well structure. In detail, it is structured as described below.

As shown in FIG. 3, the device (wafer) comprises, sequentially grown on the GaN self-standing substrate 101 formed as described above, an n-type Al_{0.1}Ga_{0.9}N cladding layer 102, an InGaN-based active layer 110 with a multiquantum well structure (MQW) composed of three 3 nm thick In_{0.15}Ga_{0.85}N well layers 111 and four 10 nm thick GaN barrier layers 112, a p-type Al_{0.1}Ga_{0.9}N cladding layer 121, and a p-type GaN contact layer 122. Further, a p-type electrode 131 is formed on the p-GaN contact layer 122 and an n-type electrode 132 is formed on the rear surface of the GaN self-standing substrate 101. The wafer is cut into each nitride semiconductor device by a dicer and is evaluated.

With respect to the substrate holder installed in the vapor phase growth apparatus used, its arithmetic mean roughness is measured 1 micrometer at its contact surface with the rear surface of the GaN self-standing substrate.

The semiconductor layers for the device are fabricated by known MOCVD. Metalorganic materials used are trimethylgallium (TMG), trimethylaluminum (TMA), trimethylindium (TMI), and biscyclopentadienylmagnesium (Cp₂Mg). Gas materials are ammonium (NH₃) and silane (SiH₄) Carrier gases used are hydrogen and nitrogen.

FIG. 4 is a graph showing the non-defective product yield of nitride semiconductor devices fabricated in Examples 1-3 and Comparative Examples 1-3. The non-defective product yield is determined such that a nitride semiconductor device with an emission wavelength falling within ±2.0 nm of a specified wavelength is defined as a non-defective product and the other nitride semiconductor device is defined as a defective product.

The nitride semiconductor devices of the invention (Examples 1-3) have all a non-defective product yield of 85% or so. This is assumed because the rear surface of the GaN self-standing substrate 101 of the nitride semiconductor device is in roughness close to the surface of the substrate holder (i.e., in the range of one tenth to equal relative to the roughness of the substrate holder), and the degree of contact can be thereby enhanced such that the GaN self-standing substrate 101 is in face-to-face contact with the substrate holder, and therefore the temperature distribution in plane of the GaN self-standing substrate 101 can be uniformed to enhance the non-defective product yield.

In contrast, the nitride semiconductor device (Comparative Example 1) using the GaN self-standing substrate with both surfaces mirror-polished has a non-defective product yield of 50%. The nitride semiconductor device (Comparative Example 2) using the GaN self-standing substrate with a rear surface arithmetic mean roughness of 1 nm has a non-defective product yield of 57%. The nitride semiconductor device (Comparative Example 3) using the GaN self-standing substrate with a rear surface arithmetic mean roughness of 100 micrometers has a non-defective product yield of 30%.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A self-standing gallium nitride-based semiconductor single crystal substrate, comprising:
a surface (Ga-face) mirror-polished; and
a rear surface (N-face) comprising an arithmetic mean roughness Ra of 1 micrometer or more and 10 micrometers or less.

2. A method of making a self-standing gallium nitride-based semiconductor single crystal substrate, comprising:
a surface treatment step that a surface (Ga-face) of the substrate is mirror-polished; and
a rear-surface treatment step that a rear surface (N-face) of the substrate is lapped and then etched.

3. The method according to claim 2, wherein:
the rear-surface treatment step is conducted such that the rear surface (N-face) comprising an arithmetic mean roughness Ra of 1 micrometer or more and 10 micrometers or less.

4. A method of making a nitride semiconductor device, comprising the step of:
growing the nitride semiconductor device on the gallium nitride-based semiconductor single crystal substrate made by the method according to claim 2 by a vapor phase growth method.

5. The method according to claim 4, wherein:
the rear-surface treatment step is conducted such that the rear surface (N-face) comprising an arithmetic mean roughness Ra of 1 micrometer or more and 10 micrometers or less.

6. A method of making a nitride semiconductor device, comprising:
providing a self-standing gallium nitride-based semiconductor single crystal substrate; and
an adjustment step that, before the gallium nitride-based semiconductor single crystal substrate is attached to a substrate holder of a vapor phase growth apparatus, the gallium nitride-based semiconductor single crystal substrate is adjusted such that its rear surface (N-face) comprises a arithmetic mean roughness Ra to be in face-to-face contact with the substrate holder.

7. The method according to claim 6, wherein:
the adjustment step comprises etching the rear surface of the substrate.

8. The method according to claim 6, wherein:
the adjustment step comprises adjusting the arithmetic mean roughness Ra to be 1 micrometer or more and 10 micrometers or less.
